(19) United States
(12) Patent Application Publication
(10) Pub. No.: US 2018/0166544 A1
(43) Pub. Date: Jun. 14, 2018

(54) OXIDE SEMICONDUCTOR THIN-FILM TRANSISTOR AND MANUFACTURING METHOD THEREOF

(71) Applicant: SILICON DISPLAY TECHNOLOGY, Yongin-si (KR)

(72) Inventors: Soon Ho CHOI, Yongin-si (KR); Sung Ryong MOON, Goyang-si (KR)

(73) Assignee: SILICON DISPLAY TECHNOLOGY, Yongin-si (KR)

(21) Appl. No.: 15/579,265

(22) PCT Filed: Jun. 30, 2015
(86) PCT No.: PCT/KR2015/006651

§ 371 Date: Dec. 4, 2017

(51) Int. Cl. H01L 29/417; H01L 29/786; H01L 29/66

(52) U.S. Cl. CPC H01L 29/41733; H01L 29/66742; H01L 29/66969; H01L 29/78693

(57) ABSTRACT

The present invention relates to an oxide semiconductor thin film transistor and a manufacturing method thereof, and the manufacturing method of the oxide semiconductor thin film transistor includes: a first step for depositing and patterning a gate layer on a substrate to form a gate electrode; a second step for depositing a gate insulation layer on the gate electrode; a third step for depositing and patterning an oxide semiconductor on the gate insulation layer; and a fourth step for treating a plasma including fluorine (F) on the oxide semiconductor.

### TECHNICAL FIELD

An exemplary embodiment of the present invention relates to an oxide semiconductor thin film transistor and a manufacturing method thereof.

### BACKGROUND ART

In general, a thin film transistor as a switching element controlling an operation of each pixel and a driving element of each pixel is used in a display device such as a liquid crystal display (LCD), an electroluminescence display (ELD) device, etc.

As a result, researches on a method of manufacturing a thin film transistor are being actively carried out, and techniques such as in Korean Patent Publication No. 10-2010-0060502 have been proposed to improve patterning accuracy of the semiconductor layer inside the thin film transistor and to reduce costs.

Recently, research and development on the thin film transistor using an oxide semiconductor as an active layer have been actively carried out.

The oxide semiconductor thin film transistor is applied to a flat display such as a TFT-LCD, an AMOLED, etc., various sensing sensors, a driving circuit, a logic circuit, etc. based on merits such as electric field mobility, a low threshold voltage near 0 V, a low leakage current, etc.

However, the oxide semiconductor thin film transistor has a problem of reliability despite the above merit, and in detail, methods to improve the stability and the reliability by compensating damage applied to the oxide semiconductor during etching for forming a source electrode and a drain electrode on an upper surface of the oxide semiconductor, and increasing the threshold voltage in a transfer characteristic with a change of the process or an additional process, are required.

### DISCLOSURE

### Technical Problem

The present invention ameliorates instability and improves reliability by executing a plasma treatment to an upper surface of an oxide semiconductor exposed between a source electrode and a drain electrode so as to compensate damage applied to the oxide semiconductor when patterning the source electrode and the drain electrode and to stabilize the surface of the oxide semiconductor through the plasma treatment.

### Technical Solution

Also, the present invention increases a threshold voltage in transfer characteristics without a change of a process or an additional process by controlling a plasma treatment time, thereby manufacturing an active driving display device and an active driving sensor on various substrates.

A manufacturing method of an oxide semiconductor thin film transistor according to the present exemplary embodiment comprises: a first step for depositing and patterning a gate layer on a substrate to form a gate electrode; a second step for depositing a gate insulation layer on the gate electrode; a third step for depositing and patterning an oxide semiconductor on the gate insulation layer; and a fourth step for treating a plasma including fluorine (F) on the oxide semiconductor.

According to another exemplary embodiment of the present invention, the third step further includes a step for forming a source electrode and a drain electrode on the patterned oxide semiconductor, and in the fourth step the plasma including fluorine (F) is treated on the oxide semiconductor exposed between the source electrode and the drain electrode.

According to another exemplary embodiment of the present invention, a fifth step for forming a source electrode and a drain electrode on the oxide semiconductor treated with the plasma may be further included.

According to another exemplary embodiment of the present invention, a step for depositing a silicon oxide protective layer on the substrate may be further included before the depositing and patterning of the gate layer.

According to another exemplary embodiment of the present invention, in the first step, the gate layer may be deposited and pattered on the oxide protective layer to form the gate electrode.

According to another exemplary embodiment of the present invention, the oxide semiconductor may be configured to be amorphous or polycrystalline, and is formed to include one among indium gallium zinc oxide (amorphous-InGaZnO₄), zinc oxide (ZnO), indium zinc oxide (IZO), indium tin oxide (ITO), zinc tin oxide (ZTO), gallium zinc oxide (GZO), hafnium indium zinc oxide (HIZO), zinc indium tin oxide (ZITO), and aluminum zinc tin oxide (AZTO).

According to another exemplary embodiment of the present invention, a fifth step for forming a passivation layer on the source electrode, the drain electrode, and the oxide semiconductor that are treated with the plasma treatment may be further included.

According to another exemplary embodiment of the present invention, the gate insulation layer or the passivation layer may include at least one of a silicon oxide layer and a silicon nitride layer.

According to another exemplary embodiment of the present invention, in the fourth step, a ZnF bonding may be formed in the oxide semiconductor by treating the plasma including fluorine (F).

According to another exemplary embodiment of the present invention, in the fourth step, a NF bonding or an InZn bonding may be formed in the oxide semiconductor by treating the plasma including nitrogen (N) and fluorine (F).

According to another exemplary embodiment of the present invention, the substrate may be one among substrates on which a polymer material is formed, including a glass substrate, a plastic substrate, and a silicon substrate, and the source electrode and the drain electrode may include at least one among molybdenum (Mo), copper (Cu), aluminum (AL), and indium tin oxide (ITO).

An oxide semiconductor thin film transistor according to an exemplary embodiment of the present invention comprises: a substrate; a gate electrode formed on the substrate; a gate insulation layer formed on the gate electrode; an oxide semiconductor formed on the gate insulation layer; and a source electrode and a drain electrode formed on the oxide semiconductor, wherein a ZnF bonding is formed in the oxide semiconductor by treating a plasma including fluorine (F), or a NF bonding or an InZn bonding is formed in the oxide semiconductor by treating a plasma including nitrogen (N) and fluorine (F).

According to another exemplary embodiment of the present invention, an oxide protective layer formed on the substrate may be further included.

According to another exemplary embodiment of the present invention, the oxide semiconductor may be configured to be amorphous or polycrystalline, and is formed to include one among indium gallium zinc oxide (amorphous-InGaZnO₄), zinc oxide (ZnO), indium zinc oxide (IZO), indium tin oxide (ITO), zinc tin oxide (ZTO), gallium zinc oxide (GZO), hafnium indium zinc oxide (HIZO), zinc indium tin oxide (ZITO), and aluminum zinc tin oxide (AZTO).

According to another exemplary embodiment of the present invention, a passivation layer formed on the source electrode, the drain electrode, and the oxide semiconductor that are treated with the plasma may be further included.

According to another exemplary embodiment of the present invention, the gate insulation layer or the passivation layer may include at least one of a silicon oxide layer and a silicon nitride layer.

According to another exemplary embodiment of the present invention, the substrate may be one among substrates on which a polymer material is formed, including a glass substrate, a plastic substrate, and a silicon substrate, and the source electrode and the drain electrode may include at least one among molybdenum (Mo), copper (Cu), aluminum (Al), and indium tin oxide (ITO).

### Advantageous Effects

According to an exemplary embodiment of the present invention, as the plasma treatment is executed to the upper surface of the oxide semiconductor exposed between the source electrode and the drain electrode, the damage applied to the oxide semiconductor when patterning the source electrode and the drain electrode may be compensated, and the oxide semiconductor surface may be stabilized through the plasma treatment such that the instability may be ameliorated and the reliability may be improved.

Also, according to an exemplary embodiment of the present invention, as the plasma treatment time is controlled to increase the threshold voltage of the transfer characteristics without the change of the process or the additional process, the manufacturing of the active driving display device and the active driving sensor on the various substrates is possible.

### DESCRIPTION OF THE DRAWINGS

FIG. 1 to FIG. 4 are views to explain an oxide semiconductor thin film transistor and a manufacturing method thereof according to an exemplary embodiment of the present invention.

FIG. 5 to FIG. 12 are views to explain an improved characteristic of a manufacturing method of an oxide semiconductor thin film transistor according to an exemplary embodiment of the present invention.

### MODE FOR INVENTION

In the following, an exemplary embodiment of the present invention will be described in detail with reference to accompanying drawings. However, in the description of the embodiments, when it is determined that a concrete description of related known functions or configurations unnecessarily obscures a gist of the present invention, a detailed description thereof will be omitted. In addition, a size of each component in the drawings may be exaggerated for explanation, and does not mean the size actually applied.

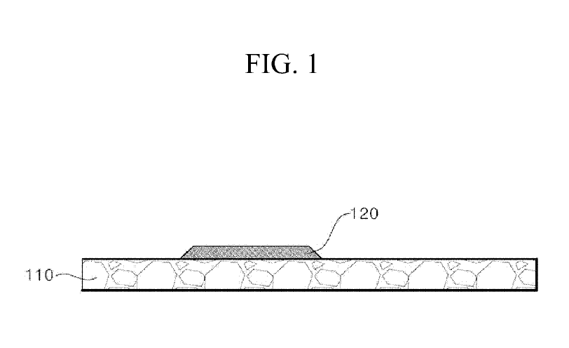

FIG. 1 to FIG. 4 are views to explain an oxide semiconductor thin film transistor and a manufacturing method thereof according to an exemplary embodiment of the present invention.

The manufacturing method of the oxide semiconductor thin film transistor according to an exemplary embodiment of the present invention will be described with reference to FIG. 1 to FIG. 4.

As shown in FIG. 1, a gate electrode 120 is firstly formed on a substrate 110.

When forming the gate electrode 120, a gate layer is deposited on the substrate 110 and is patterned to form the gate electrode 120.

The substrate 110 may be configured as one among substrates on which a polymer material is formed, including a glass substrate, a plastic substrate, and a silicon substrate.

In this case, the gate electrode 120 may be formed on an oxide protective layer after a silicon oxide protective layer is firstly deposited on the substrate 110.

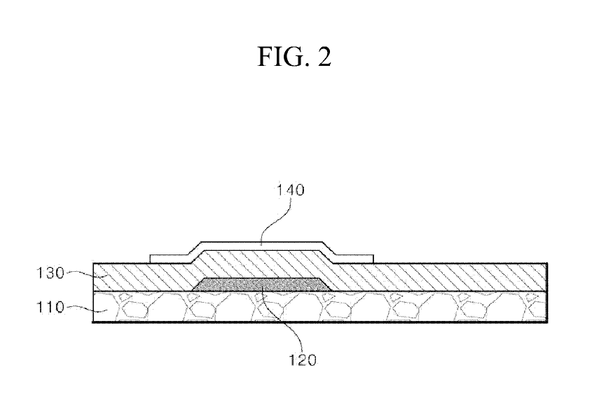

Next, a gate insulation layer 130 is deposited and formed on the above-configured gate electrode, as shown in FIG. 2.

In this case, the gate insulation layer 130 may be configured to include at least one of a silicon oxide layer and a silicon nitride layer.

Also, an oxide semiconductor 140 is deposited and patterned on the above-formed gate insulation layer 130.

In this case, the oxide semiconductor 140 according to an exemplary embodiment of the present invention may be configured to be amorphous or polycrystalline, and is formed to include one among indium gallium zinc oxide (amorphous-InGaZnO₄), zinc oxide (ZnO), indium zinc oxide (IZO), indium tin oxide (ITO), zinc tin oxide (ZTO), gallium zinc oxide (GZO), hafnium indium zinc oxide (HIZO), zinc indium tin oxide (ZITO), and aluminum zinc tin oxide (AZTO).

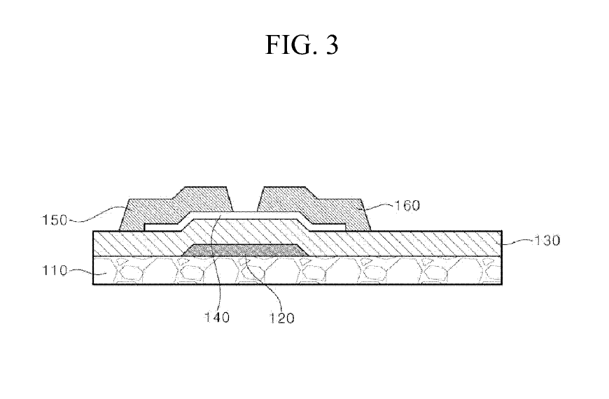

Next, as shown in FIG. 3, the oxide semiconductor 140 is treated by using a plasma including fluorine (F).

In this case, the plasma treatment may be executed directly on the oxide semiconductor, or the plasma treatment may be executed to the upper surface of the oxide semiconductor 140 between a source electrode 150 and a drain electrode 160 after forming the source electrode 150 and the drain electrode 160.

According to an exemplary embodiment of the present invention, by executing the plasma treatment, the oxide semiconductor 140 may be protected when forming the source electrode 150 and the drain electrode 160 later, or the damage applied to the oxide semiconductor 140 when patterning the source electrode 150 and the drain electrode 160 may be compensated.

On the other hand, according to an exemplary embodiment of the present invention, ZnF bonding may be formed in the oxide semiconductor by the treatment using the plasma including fluorine (F) on the oxide semiconductor 140, or NF bonding or InZn bonding may be formed in the oxide thin film in the oxide semiconductor by the treatment using the plasma including nitrogen (N) and fluorine (F).

As above-described, by executing the plasma treatment on the oxide semiconductor 140, stabilization of the surface of the oxide semiconductor 140 is possible such that instability may be ameliorated and reliability may be improved, and the threshold voltage of the transfer characteristics may be increased by controlling the plasma treatment time without a process change or an additional process such that the manufacturing of the active driving display device and the active driving sensor are possible on various substrates.

On the other hand, the source electrode 150 and the drain electrode 160 may be configured by including at least one among molybdenum (Mo), copper (Cu), aluminum (AL), and indium tin oxide (ITO).

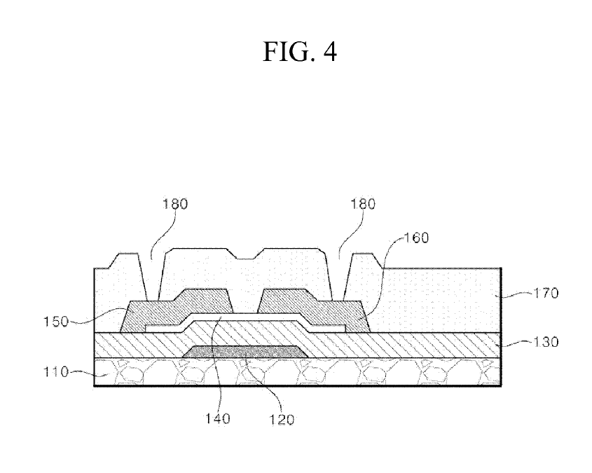

Next, as shown in FIG. 4, a passivation layer 170 may be formed on the source electrode 150, the drain electrode 160, and the oxide semiconductor 140 to which the plasma treatment is subjected.

On the other hand, the gate insulation layer 130 or the passivation layer 170 may include at least one of the silicon oxide layer and the silicon nitride layer.

Also, the passivation layer 170 may have a contact hole 180 partially exposing the upper surface of the source electrode 150 and the drain electrode 160.

Hereinafter, a configuration of the oxide semiconductor thin film transistor according to an exemplary embodiment of the present invention will be described with reference to FIG. 4.

As shown in FIG. 4, the oxide semiconductor thin film transistor according to an exemplary embodiment of the present invention includes the substrate 110, the gate electrode 120, the gate insulation layer 130, the oxide semiconductor 140, the source electrode 150, the drain electrode 160, and the passivation layer 170.

The gate electrode 120 may be formed on the substrate 110, the gate insulation layer 130 may be formed on the gate electrode 120, the oxide semiconductor 140 may be formed on the gate electrode 120, the source electrode 150 and the drain electrode 160 may be formed on the oxide semiconductor 140, and the passivation layer 170 may be formed on the source electrode 150, the drain electrode 160, and the oxide semiconductor 140.

In this case, the substrate 110 may be configured as one among substrates on which the polymer material is formed, including a glass substrate, a plastic substrate, and a silicon substrate, and an oxide protective layer may be additionally formed on the substrate 110.

Also, the source electrode 150 and the drain electrode 160 may be configured by including at least one among molybdenum (Mo), copper (Cu), aluminum (AL), and indium tin oxide (ITO).

On the other hand, the oxide semiconductor 140 according to an exemplary embodiment of the present invention may be configured to be amorphous or polycrystalline, and is formed to include one among indium gallium zinc oxide (amorphous-InGaZnO₄), zinc oxide (ZnO), indium zinc oxide (IZO), indium tin oxide (ITO), zinc tin oxide (ZTO), gallium zinc oxide (GZO), hafnium indium zinc oxide (HIZO), zinc indium tin oxide (ZITO), and aluminum zinc tin oxide (AZTO).

In this case, according to an exemplary embodiment of the present invention, ZnF bonding may occur in the oxide semiconductor by the treatment using the plasma including fluorine (F) on the oxide semiconductor 140, or NF bonding or InZn bonding may occur in the oxide semiconductor by the treatment using the plasma including nitrogen (N) and fluorine (F).

Also, the gate insulation layer 130 or the passivation layer 170 may be configured by including at least one of the silicon oxide layer and the silicon nitride layer, and the passivation layer 170 may have the contact hole 180 partially exposing the upper surface of the source electrode 150 and the drain electrode 160.

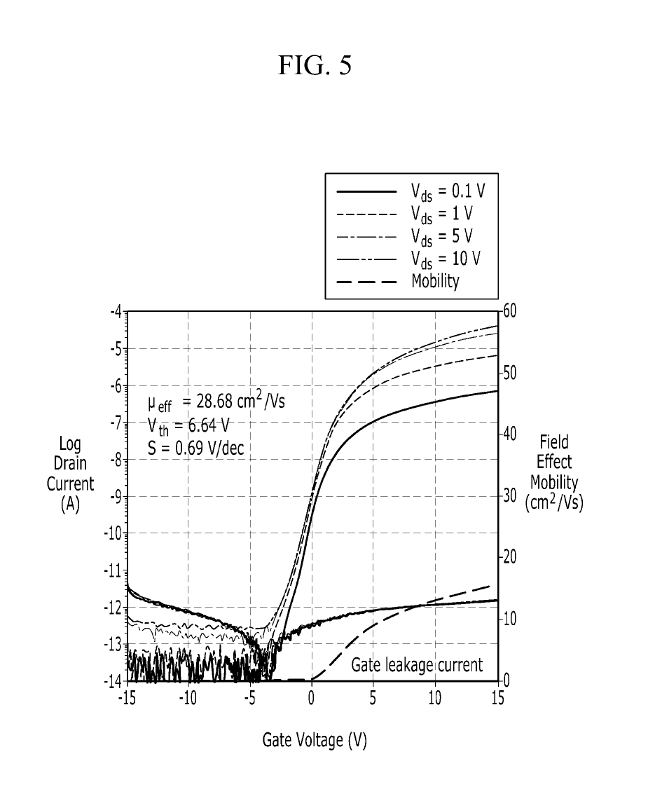

FIG. 5 to FIG. 12 are views to explain an improved characteristic of a manufacturing method of an oxide semiconductor thin film transistor according to an exemplary embodiment of the present invention.

Next, the improved characteristic of the manufacturing method of the oxide semiconductor thin film transistor according to an exemplary embodiment of the present invention will be described with reference to FIG. 5 to FIG. 12.

FIG. 5 is a graph showing a transfer characteristic curve (a transfer curve) and electric field mobility of an oxide semiconductor thin film transistor of a BCE structure according to a conventional art.

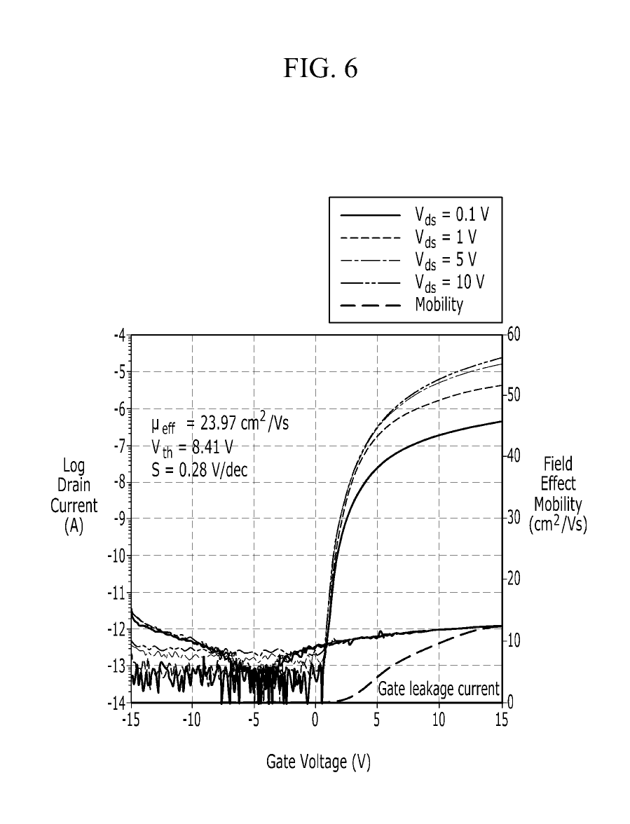

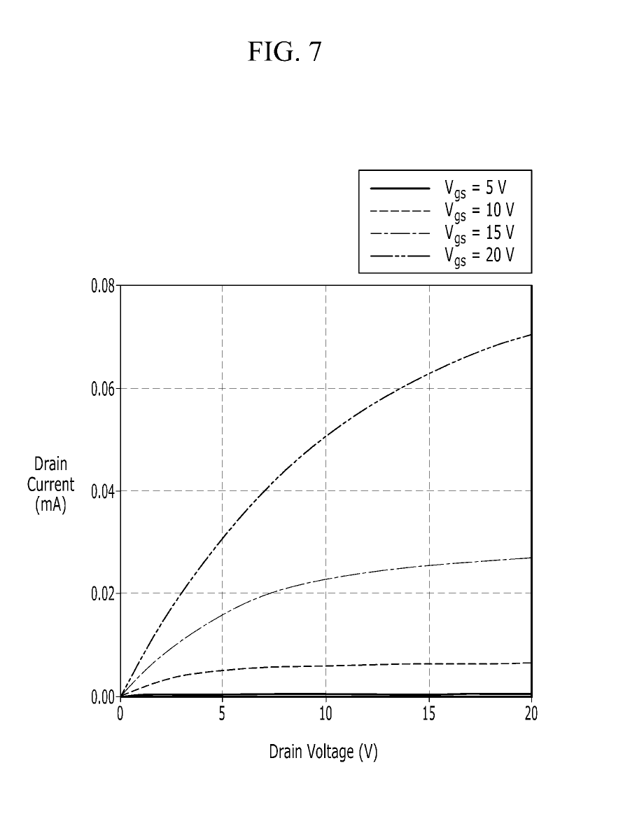

FIG. 6 is the graph showing the transfer characteristic curve (the transfer curve) of the oxide semiconductor thin film transistor according to an exemplary embodiment of the present invention, and FIG. 7 is the graph showing a current curve (an output curve) of the oxide semiconductor thin film transistor according to an exemplary embodiment of the present invention.

FIG. 5 and FIG. 6 show the current voltage characteristic of the oxide semiconductor thin film transistor having an active layer when the drain voltage is 0.1 V, 1 V, 5 V, and 10V.

Referring to the graph of FIG. 6, compared with the transfer curve and the electric field mobility of the oxide semiconductor thin film transistor of the BCE (back-channel-etched) structure according to the conventional art of FIG. 5, it may be confirmed to implement the thin film transistor having performance of which the threshold voltage increases and simultaneously a sub-threshold swing (SS) decreases.

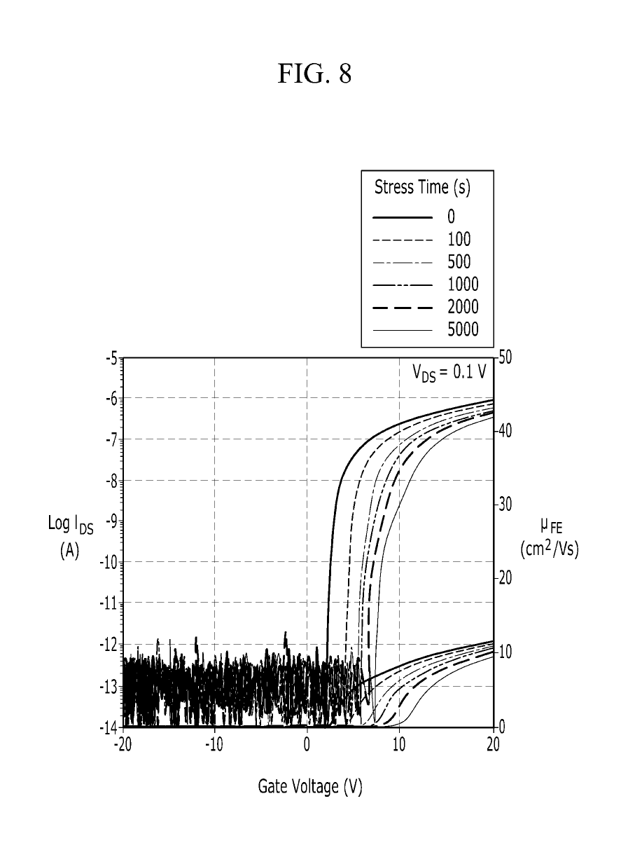

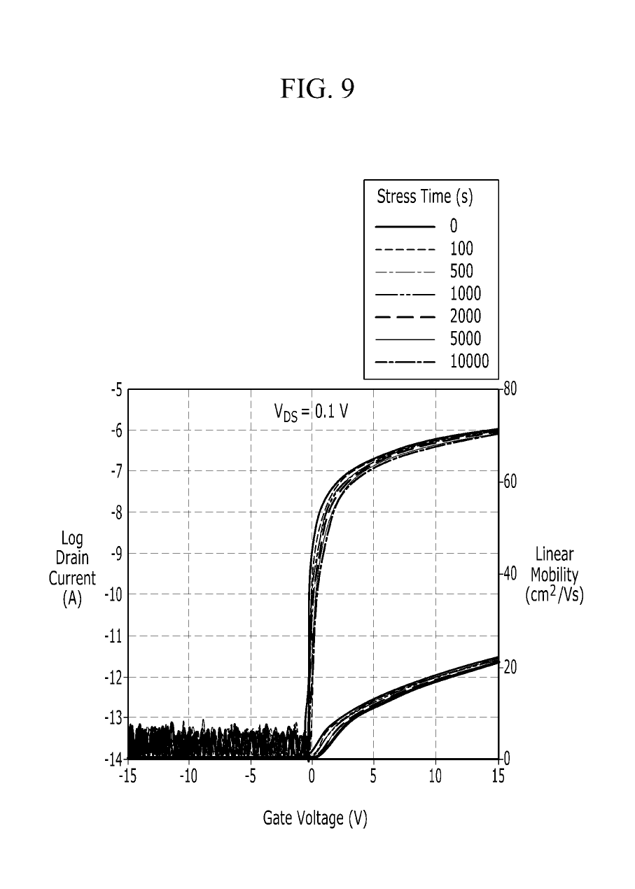

FIG. 8 and FIG. 9 show a stress test result for securing environmental stability of the oxide semiconductor thin film transistor. It is a graph showing a situation where a positive voltage is applied to each circuit terminal. In this situation, VGS=+30 V is applied to the gate electrode.

FIG. 8 shows a positive bias stress (PBS) (VGS=30 V) characteristic of the oxide TFT according to a conventional manufacturing method. It may be confirmed that a positive shift of the threshold voltage is generated depending the stress time.

FIG. 9 is a view showing a positive bias stress (PBS) (VGS=30 V) characteristic of an oxide semiconductor thin film transistor according to an exemplary embodiment of the present invention.

To convert the thin film transistor into “a turn-on state” and “a turn-off state”, the positive voltage or the negative voltage is applied to each circuit terminal. Therefore, in order to ensure electrical stability of the transistor, when the positive voltage is applied, an important characteristic evaluation factor of the thin film transistor is that a positive shift of the threshold voltage does not occur.

When comparing FIG. 8 and FIG. 9, it may be confirmed that the stability of the electrical characteristic is excellent with respect to the positive bias stress.

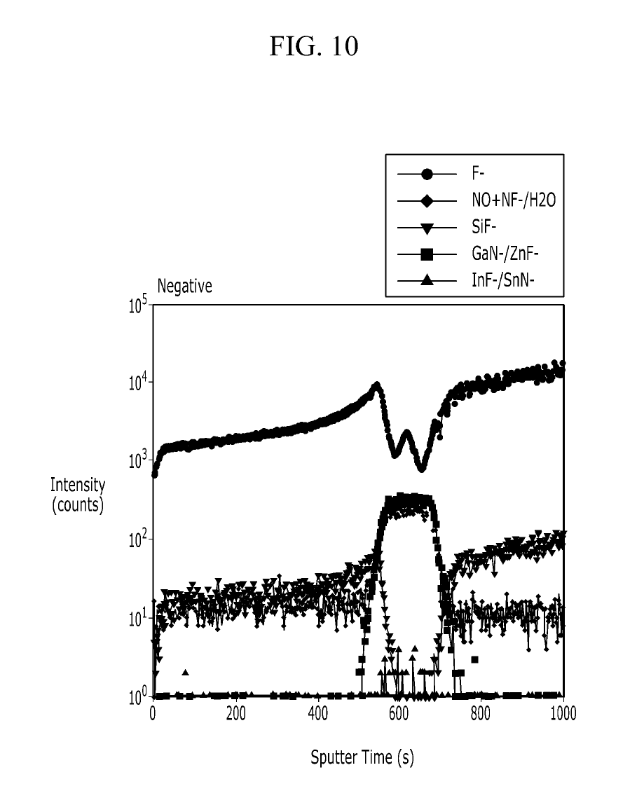

FIG. 10 is a graph of TOF-SIMS measurement of a surface treated with the plasma on the surface of the oxide semiconductor 140 exposed between the source electrode 150 and the drain electrode 160 according to an exemplary embodiment of the present invention. It may be confirmed that a large amount of fluorine is found on the surface of the oxide semiconductor 140.

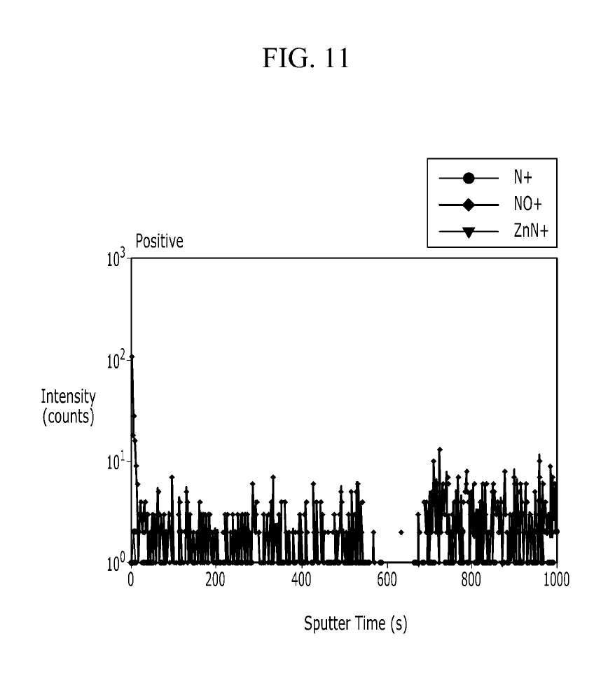

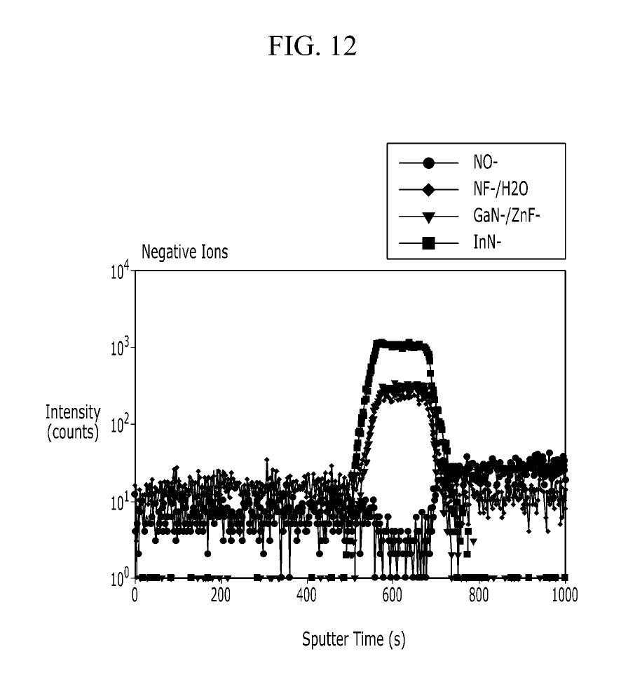

FIG. 11 are FIG. 12 are graphs of TOF-SIMS measurement of the surface treated with the plasma on the surface of the oxide semiconductor 140 exposed between the electrodes 150 and 160 according to an exemplary embodiment of the present invention. It may be confirmed that a large amount of nitrogen is found on the surface.

Simply put, there is a degradation phenomenon in which a positive voltage shift of the threshold voltage occurs depending on the stress time for the positive voltage applied to the gate electrode, and this phenomenon may be explained by electron trapping. As fluorine and nitrogen on the surface reduce the electron trapping by treating the plasma using at least one among fluorine (F), nitrogen (N), gallium nitride (GaN), and NF₃ based on the TOF-SIMS data above, it may be confirmed that the stability and the reliability are improved by compensating the damage applied to the oxide semiconductor during the etching for forming the source electrode and the drain electrode of the oxide semiconductor.

In the detailed description of the present invention as described above, an exemplary embodiment has been described. However, various modifications are possible within the scope of the present invention. The technical idea of the present invention is not restricted to the above-mentioned embodiment of the present invention, and it should be determined not only by the claims, but also by equivalents to the scope of the claims.

1. A method for manufacturing an oxide semiconductor thin film transistor, comprising:
a first step for depositing and patterning a gate layer on a substrate to form a gate electrode;
a second step for depositing a gate insulation layer on the gate electrode;
a third step for depositing and patterning an oxide semiconductor on the gate insulation layer; and
a fourth step for treating a plasma including fluorine (F) on the oxide semiconductor.

2. The method of claim 1, wherein
the third step further includes
a step for forming a source electrode and a drain electrode on the patterned oxide semiconductor, and
in the fourth step,
the plasma including fluorine (F) is treated on the oxide semiconductor exposed between the source electrode and the drain electrode.

3. The method of claim 1, further comprising
a fifth step for forming a source electrode and a drain electrode on the oxide semiconductor treated with the plasma.

4. The method of claim 1, further comprising,
before the first step,
a step for depositing a silicon oxide protective layer on the substrate.

5. The method of claim 4, wherein,
in the first step,
the gate layer is deposited and pattered on the oxide protective layer to form the gate electrode.

6. The method of claim 1, wherein
the oxide semiconductor is configured to be amorphous or polycrystalline, and is formed to include one among indium gallium zinc oxide (amorphous-InGaZnO₄), zinc oxide (ZnO), indium zinc oxide (IZO), indium tin oxide (ITO), zinc tin oxide (ZTO), gallium zinc oxide (GZO), hafnium indium zinc oxide (HIZO), zinc indium tin oxide (ZITO), and aluminum zinc tin oxide (AZTO).

7. The method of claim 1, further comprising
a fifth step for forming a passivation layer on the source electrode, the drain electrode, and the oxide semiconductor that are treated with the plasma treatment.

8. The method of claim 7, wherein
the gate insulation layer or the passivation layer includes at least one of a silicon oxide layer and a silicon nitride layer.

9. The method of claim 1, wherein,
in the fourth step,
a ZnF bonding is formed in the oxide semiconductor by treating the plasma including fluorine (F).

10. The method of claim 1, wherein,
in the fourth step,
a NF bonding or an InZn bonding is formed in the oxide semiconductor by treating the plasma including nitrogen (N) and fluorine (F).

11. The method of claim 1, wherein
the substrate is one among substrates on which a polymer material is formed, including a glass substrate, a plastic substrate, and a silicon substrate, and
the source electrode and the drain electrode include at least one among molybdenum (Mo), copper (Cu), aluminum (AL), and indium tin oxide (ITO).

12. An oxide semiconductor thin film transistor comprising:
a substrate;
a gate electrode formed on the substrate;
a gate insulation layer formed on the gate electrode;
an oxide semiconductor formed on the gate insulation layer; and
a source electrode and a drain electrode formed on the oxide semiconductor,
wherein a ZnF bonding is formed in the oxide semiconductor by treating a plasma including fluorine (F), or a NF bonding or an InZn bonding is formed in the oxide semiconductor by treating a plasma including nitrogen (N) and fluorine (F).

13. The oxide semiconductor thin film transistor of claim 12, further comprising
an oxide protective layer formed on the substrate.

14. The oxide semiconductor thin film transistor of claim 12, wherein
the oxide semiconductor is configured to be amorphous or polycrystalline, and is formed to include one among indium gallium zinc oxide (amorphous-InGaZnO₄), zinc oxide (ZnO), indium zinc oxide (IZO), indium tin oxide (ITO), zinc tin oxide (ZTO), gallium zinc oxide (GZO), hafnium indium zinc oxide (HIZO), zinc indium tin oxide (ZITO), and aluminum zinc tin oxide (AZTO).

15. The oxide semiconductor thin film transistor of claim 12, further comprising
a passivation layer formed on the source electrode, the drain electrode, and the oxide semiconductor that are treated with the plasma.

16. The oxide semiconductor thin film transistor of claim 15, wherein
the gate insulation layer or the passivation layer includes at least one of a silicon oxide layer and a silicon nitride layer.

17. The oxide semiconductor thin film transistor of claim 12, wherein
the substrate is one among substrates on which a polymer material is formed, including a glass substrate, a plastic substrate, and a silicon substrate, and
the source electrode and the drain electrode include at least one among molybdenum (Mo), copper (Cu), aluminum (Al), and indium tin oxide (ITO).
